(19) United States
(12) Patent Application Publication
(10) Pub. No.: US 2009/0200250 A1
(43) Pub. Date: Aug. 13, 2009

(54) Cleanliness-improved wafer container

(75) Inventor: Boris Kesil, San Jose, CA (US)

Correspondence Address: BORIS KESIL;MULTIMETRIXS, LLC, 1040 Di Giulio Avenue #200, Santa Clara, CA, 95050, US

(73) Assignee: MultiMetrixs, LLC

(21) Appl. No.: 12/012,984

(22) Filed: Feb. 7, 2008

(51) Int. Cl. H01L 21/673

(52) U.S. Cl. 211/41.12

(57) ABSTRACT

A wafer container made from a polymer material with inner walls of the container coated with a thin easily washable wear-resistant and scratch-resistant barrier layer of SiO₂ for preventing penetration of products of diffusion of polymers, such as free radicals, into the interior space of the carrier that retains a wafer. The SiO₂ coatings on the walls of the container are applied by the PECVD process. The wafer container of the invention can be manufactured at low cost by molding it from a less expensive and lower grade polymer.

### FIELD OF THE INVENTION

The present invention relates to the field of semiconductor production, and more particularly, to devices for storage and transportation of semiconductor wafers used for the manufacture of semiconductor devices in mini-environment. More specifically, the invention relates to cleanliness-improved wafer containers known as FOUPs, FOSBs, etc. that are used for storage of the wafers in spaces that form mini-environment and that have standard mechanical interfaces. In principle, the invention relates to completely closable wafer-storage boxes having standard mechanical interfaces.

### BACKGROUND OF THE INVENTION

It is well known that semiconductor processing requires operation under very clean conditions. At the present time the requirement of purity of semiconductor wafers is very stringent, and, therefore, it is required that the number of contaminant particles that are introduced into the wafer container from outside or that are formed inside the wafer container be maintained at a minimal possible level.

Contamination is the single biggest cause of yield loss in the semiconductor industry. As the size of integrated circuitry has continued to be reduced, the size of particles, which can contaminate an integrated circuit, has also become smaller making minimization of contaminants all the more critical. Therefore, one important direction of maintaining wafer in an ultra-clean state is elimination of sources that produce foreign or contamination particles, which can precipitate onto the wafer surface.

Silicon wafers are handled in special plastic cassettes and carried in special closed containers. Despite the fact that wafer transportation and processing has to be contamination free, these processes introduce organic contaminants and particles. In order to improve the cleanliness of the semiconductor production, the so-called mini-environment has been introduced. This means that the wafers are no longer handled in open cassettes, but in closed, clean boxes which are only opened inside the processing equipment and in closed spaces having high degree of cleanliness. Here, the term “wafer container” covers the sealable “closed boxes” used in the semiconductor production and known as SMIF (Standard Mechanical InterFace) boxes, FOUP boxes (Front Opening Unified Pod), FOSB (Front Opening Shipping Boxes), etc.

SMIF stands for those boxes that include an open cassette, which is unloaded through the bottom of the SMIF pod. For 300 mm silicon wafers, the design of the mini-environment boxes has been changed and now becomes a state of the art. These boxes are opened from the front side, and the equipment robot unloads the wafers directly from the FOUP. There are also more simple boxes available just for transport. The FOSB boxed have a more simple construction and are designed just for transportation.

Contaminants in the form of particles may be generated by abrasion such as rubbing or scraping of the carrier with the wafers or disks, with the carrier covers or enclosures, with storage racks, with other carriers or with processing equipment. Additionally, particulates such as dust can be introduced into the enclosures through the openings or joints in the covers and/or enclosures.

Containers are generally configured to arrange the wafers or disks in slots and to support the wafers or disks by or near their peripheral edges. The wafers or disks are conventionally removable from the containers in a radial direction upwardly or laterally. The containers may have a shell portion with a lower opening, a door to latch into the lower opening, and a discrete carrier that rests on the door. These configurations, known as SMIF pods, are illustrated in U.S. Pat. No. 4,995,430 issued in 1991 to A. Borona, et al. and U.S. Pat. No. 4,815,912 issued in 1989 to G. Money, et al. Additionally, FOUP- or FOSB-type wafer container assemblies can have front openings with doors that latch onto front openings, which are described in, for example, U.S. Pat. No. 6,354,601 issued to D. Krampotich et al, in 2002.

In certain configurations, the bottom covers or doors, front doors or the container portions have been provided with openings or passageways to facilitate the introduction and/or exhaustion of gases such as nitrogen or other purified gasses, into the wafer container assemblies to displace ambient air that might have contaminants. Furthermore, some containers employ filter plugs to reduce the amount of particular contaminants that enter the container assemblies during purging. However, conventional attachment and sealing between the operation element, i.e. the filter, and the housing of the seal is by the way of rigid plastic housings and O-rings. Wafer containers known in the art have also utilized various connection or coupling mechanisms for fluidly interfacing the flow passageways of the wafer containers to fluid supply and pressure or vacuum sources. Such attachment and sealing requires specialized components, which may be of complex configuration.

However, the wafer containers cannot completely protect the wafers from contamination with particles. For example, contamination and contaminants can be generated and introduced to wafers or substrates through the handling equipment. For example, particulates can be generated mechanically by wafers as they are inserted into and removed from wafer carriers, and as doors are attached and removed from the carriers, or they can be generated chemically in reaction to different processing fluids. Contamination can also be the result of out-gassing on the carrier, biological sources due to human activity, etc. Contamination can also accumulate on the exterior of a carrier as the carrier is transported from station to station during processing.

In view of the above, the wafer containers are often subjected to cleaning by washing. However, the surfaces of the polymer materials are not easily washable. Furthermore, the polymeric materials are soft and easily scratchable, and the thus formed scratches or microcracks that occur due to deformation and deterioration serve as sources of accumulated contaminants, which cannot be easily removed by washing.

Some other examples of wafer containers of different types which are nowadays used in the industry and to which the present invention can be applicable are the following: a wafer container of the type shown in the drawings of U.S. Pat. No. 6,926,017 issued in 2005 to D. Halbmaier and relating to a wafer container washing apparatus; a front opening substrate container with bottom plate disclosed in U.S. Pat. No. 7,201,276 to J. Burns, et al. in 2007; a substrate container described in U.S. Pat. No. 7,316,325 issued in 2008 to J. Burns, et al.; and a substrate storage container described in U.S. Patent Application Publication No. 20070151897 (inventor: T. Nakayama, et al.) where the wafer-supporting ribs are made not in a removable cartridge but in the form of ribs on the inner walls of the container formed by a plurality of parallel horizontal plates embedded in the material of the container casing.

Attempts have been made heretofore to develop wafer-carriers with means for eliminating particle-forming sources. For example, U.S. Patent Application Publication No. 20060216942 published in 2006 (inventors, G. Kim) discloses a wafer-supporting cartridge having a reduced contact area of the carrier with the wafer surface. When the contacting area between the carrier and the wafer is large, static electricity and friction-induced formation of foreign particles occur and the foreign particles adhere to the wafer. Moreover, when foreign particles adhere to a wafer, the yield in semiconductor manufacturing is also reduced. In the aforementioned invention provides the construction of the wafer-storage box having a cartridge with geometry having reduced wafer-supporting surfaces.

Many other patents and patent applications aimed at the solution of the cleanness problem by providing particle-proof wafer containers are known (see, e.g., U.S. Pat. No. 5,780,127 issued in 1998 to K. Mikkelsen, U.S. Pat. No. 7,316,325 issued in 2008 to J. Burns, et al., etc.).

It is a very important gist in the semiconductor production line to improve the device yield. The major cause of lessening the device yield is the existence of the aforementioned contaminant particles consisting of dust, organic substances, and so forth.

It is, therefore, proposed, e.g., in U.S. Pat. No. 6,926,029 issued in 2005 to K. Inoue, et al. to make use of an C-type SMIF system provided with a sealed wafer pod in place of an open cassette which is used in the art of the semiconductor wafer transportation. By means of the wafer pod, it is possible to maintain dust-free wafers because the wafers can be accepted, transported and stored in a sealed box implemented with the wafer pod. Furthermore, even if the environment around the process chambers is not so purified, it is possible to conduct the wafer transportation between the process chambers with the wafers free from contaminant particles. A container for storing substrates proposed in U.S. Pat. No. 6,926,029 is composed of a box for accommodating the substrates, and a closure member for sealingly closing the box by tightly fixing the closure member to the opening of the box. The container is provided with means for temporarily storing a sealing gas and introducing the sealing gas into the box. Also, the container for storing substrates is provided with means for temporarily forming a low pressure space for the purpose of evacuating the gas inside of the box by transferring the gas to the low pressure space.

According to U.S. Pat. No. 4,739,882 issued in 1988 to M. Parikh, et al., the wafer container is provided with a removable liner for surrounding the cassette in order to protect it from contamination with airborne particles of dust and chemicals. In a preferred embodiment, the liner comprises a top liner located between the box top and the box base, made of a semi-rigid material which maintains a concave shape and surrounds the cassette or holder independently of any mechanical support. In another preferred embodiment, the liner further includes a base liner which is adapted to fit on the surface of the box door. The base liner has a sealing lip around its perimeter for exerting a force between the base and the box door for encouraging a dust-tight seal therebetween. The top liner includes a compression means for exerting a force between the box top and box base. The top liner sits on the box base.

Typically, the top liner is a thin, flexible plastic liner which requires mechanical support to be held in a tent shape. The top liner is made from a non-contaminating material such as a thermoplastic, examples of which are vinyl, acrylic or fluoroplastic. Thermoplastics can be conformed by well-known techniques into relatively thin or thick transparent films. In any embodiment, such thermoplastic films are manufactured by processes which result in a reduced number of contaminant particles. A fluoroplastic is a generic name for polytetrafluoroethylene and its copolymers. One such well known fluoroplastic is TEFLON (a trade mark of du Pont).

The liners are essentially disposable. Typically, a liner is destroyed after one or several uses. It is expected that a liner would last 1 week to 3 weeks under expected processing conditions. Although the liner environment is as clean as possible, contaminants generated by bumping as mentioned above are present. The contaminants collected on the external surface of the liner cause the liner to become dirty and become a potential source of contamination for the subsequent processing steps at the opening of the SMIF box. By replacing the liner, the container is restored to its original “clean” state without the need to replace the entire SMIF box itself. Although particulate contamination was significantly reduced thanks to the presence of such liners, contaminants were still noticed onto the wafer surfaces.

Nevertheless, foreign particles of contaminants introduced into the wafer container from outside or formed inside the wafer carries as a result of friction, etc., are not the only source of wafer contamination. It is known that wafer containers are typically formed of injection molded plastics such as polycarbonate (PC), acrylonitrile butadiene styrene (ABS), polypropylene (PP), polyethylene (PE), perfluoroalkoxy (PFA), and polyetheretherketone (PEEK). It must be recognized that a material that is ideal for one carrier function is typically not the ideal material for a different function of the same carrier. For example, PEEK is a material that has ideal abrasion resistance characteristics for wafer contact portions, but is difficult to mold and cost prohibitive relative to other plastics. However, all these materials have a fundamental disadvantage: polymer substance contains light and short molecules, such as monomers, and their fragments, such as free radicals. These molecules can diffuse through the polymer surface and exit into outer space, which in reality continuously happens during entire polymer's lifetime. Such products of diffusion usually get deposited onto the wafer surface where they form island-like structure and even continuous organic films. Over extended period of wafer storage in the plastic container the thickness of such a deposition may rich tens of angstroms. This disadvantage results in necessity to introduce additional procedures of contamination removal in between the critical operations. Replacement of the polymers by fused silica, glass and/or other materials not having said problems is in general cost ineffective and complex.

On the other hand, it is known to apply protective layers of silicon dioxide (hereinafter referred to as SiO₂) onto the polymeric surfaces by plasma-enhanced chemical gas phase deposition (PECVD) from a gaseous organosilicon with an excess of oxygen. Such a process is described, e.g., in U.S. Pat. No. 6,180,191 issued in 2001 to J. Felts. The process is exemplified by application of a gas-proof and liquid-proof barrier coating onto the inner surfaces of bottles. A gas inlet, which also serves as a counter electrode, is located inside of a vacuum chamber made of an electrically insulating material. A container is mounted on a mandrel mounted on the gas inlet. The chamber is evacuated to a subatmospheric pressure. A process gas is then introduced into the container through the gas inlet. The process gas is ionized by coupling RF power to the main electrode located adjacent an exterior surface of the chamber and to the gas inlet which deposits a plasma enhanced chemical vapor deposition (PECVD) thin film onto the interior surface of the container.

However, the method and apparatus of the type mentioned in U.S. Pat. No. 6,180,191 are not applicable for efficient application of uniform protective coatings onto the inner walls of the wafer containers. This is because in the apparatus of the above patent the coating operation is carried out in a vacuum chamber that contains a large number of small-volume bottles or similar small containers. On the other hand, a wafer container is an object that occupies a volume about several ten times greater than a bottle processed by the apparatus and method of U.S. Pat. No. 6,180,191, and processing of several such large objects in vacuum will require a vacuum chamber of a huge size which is economically unjustifiable and extremely non-productive. Furthermore, the shape of the antenna of the aforementioned patent cannot generate plasma that will produce uniform coating and that will have conformity to the inner walls of the container.

Besides, the applicant is unaware of any known wafer containers that has the inner surface coated with a thin barrier film, which is well washable, scratch- and wear-resistant, and not penetrable to volatile organic radicals and monomers present in polymeric material of the container.

### OBJECTS AND SUMMARY OF THE INVENTION

It is an object of the present invention to provide a wafer container, which has the inner surface coated with a thin barrier layer, such as a SiO₂ layer, for preventing diffusion of free radicals of the polymer material of the container casing into the interior space of the container that retains semiconductor wafers. It is another object to provide the aforementioned barrier SiO₂ layer having a thickness sufficient for protecting the surface of the wafer from contamination with volatile organic substances. It is a further object to provide a wafer container with inner walls that are easily washable, resistant to wear and scratching, and do not produce contaminant particles caused by friction. A further object is to apply the aforementioned layer by the PECVD method. A still further object is to reduce the manufacturing cost of the wafer container by molding it from a less expensive and lower grade polymers, e.g., from a polymer with a relatively high content of low-molecular-weight fragments.

Although the wafer container of the present invention may be of any suitable type, hereinafter it will be exemplified by a wafer container, e.g., a FOUP, which typically has a shape of a box having one side open for loading and unloading wafers, manually or with the use of a mechanical arm of an industrial robot. The FOUP of the invention has a disconnectable cover that can sealingly close the container. Wafer containers of the invention may have other openings, e.g., for the supply of a washing fluid or a treating gas, but in general all these openings are sealable, and the invention relates to a wafer container of any configuration that allows insertion of a special coating apparatus into the interior of the wafer container with means for sealing the open end of the container, e.g., by using standard mechanical interface as a sealing element of vacuum system. The apparatus and method of application of a protective barrier film onto the inner walls of the wafer container are subjects of a co-pending U.S. Patent Application No. ______.

The wafer container can be made by molding from polymer materials such as polycarbonate (PC), acrylonitrile butadiene styrene (ABS), polypropylene (PP), polyethylene (PE), perfluoroalkoxy (PFA), or polyetheretherketone (PEEK). Normally, the inner walls of the FOUP are smooth and the wafers are supported by special removable cartridges. In some cases, the cartridge can be secured to the casing of the wafer container or may be provided with the wafer-supporting ribs of the type shown in aforementioned U.S. Patent Application Publication No. 20070151897. The wafers are spaced at equal distances sufficient for insertion of an end-effector used for gripping the wafer edges and extracting the wafer from the FOAP.

A distinguishing feature of the wafer carrier of the present invention is that the inner walls of this sealable container as wall as the inner surface of the container's cover are coated with a thin uniform barrier layer of an easily washable, wear and scratch-resistant material such as SiO₂. The thickness of this layer ranges from 100 to 500 Angstroms. The layer is obtained by inducing a reduced pressure in the interior of the wafer container and depositing a barrier layer impermeable to organic radicals of the polymer onto the polymeric surfaces of the container by plasma-enhanced chemical gas phase deposition (PECVD) that is performed in vacuum from a gaseous organosilicon with an excess of oxygen. An example of the aforementioned gaseous organosilicon is gaseous silane with an excess of oxygen. Another distinguishing feature is that the barrier layer is formed with the PECVD process in vacuum formed inside the interior of the wafer carrier itself, instead of a conventional PECVD process, which is carried out by placing the objects to be coated into a large vacuum chamber. The sealable structure of the wafer carrier of the invention satisfies this condition. In an alternative modification where the wafer-supporting ribs are integrally embedded in the inner walls of the container, the ribs, which comprise strip-like elements, can be pre-coated prior to the molding operation.

### BRIEF DESCRIPTION OF THE DRAWINGS

FIG. 1 is a three-dimensional view of a FOUP of the invention in the form of a box with an open front side and with the cover removed.

FIG. 2 is a three-dimensional view of the cover for the FOUP casing of FIG. 1.

FIG. 3 is a fragmental sectional view along line III-III of FIG. 1 with exaggerated thickness of the coating shown not in proportion.

FIG. 4 is a three-dimensional view of the FOUP of the invention with wafer-supporting edges formed on the inner walls of the FOUP by pre-coated strips inserted into the pre-coated inner walls of the container.

FIG. 5 is a fragmental sectional view along line V-V of FIG. 4.

### DETAILED DESCRIPTION OF THE INVENTION

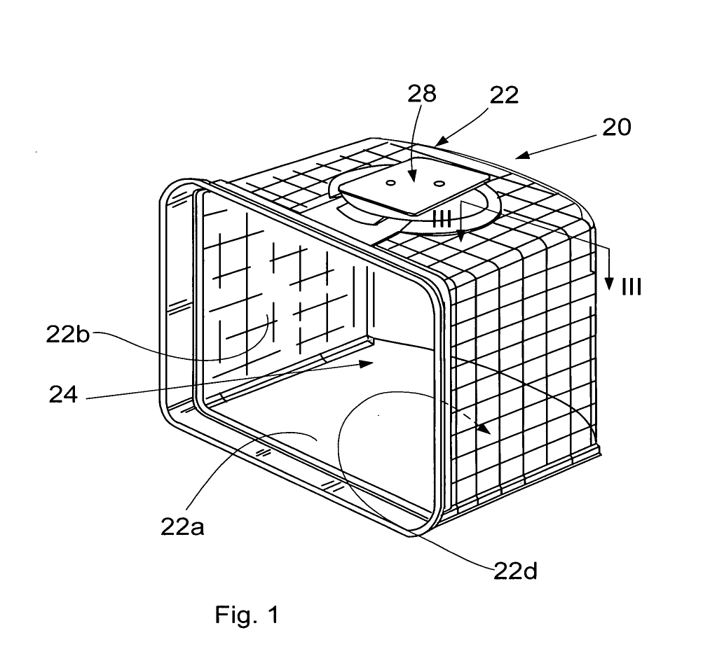

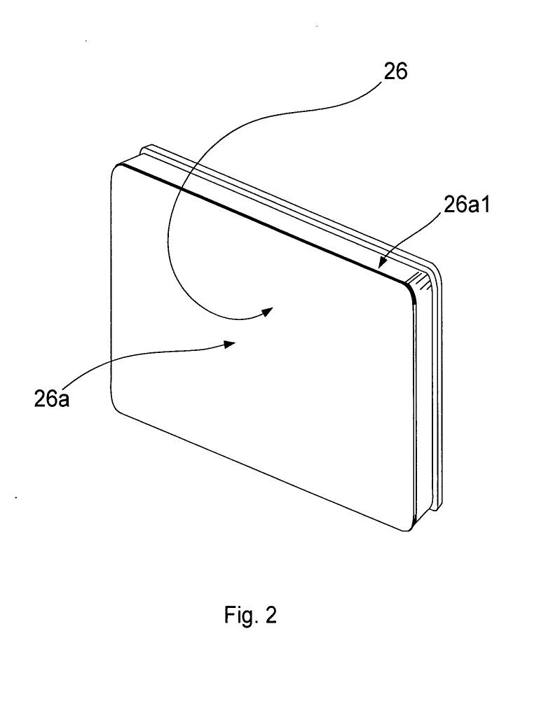

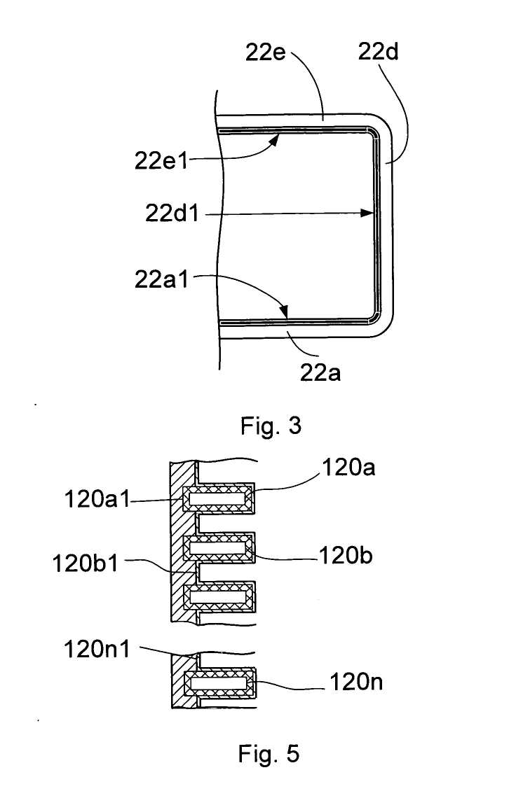

FIG. 1 is a three-dimensional view of a FOUP 20 in accordance with one modification of the invention. The FOUP 20 is made in the form of a box 22 with an open front side 24 and with the cover removed. The cover 26 is shown in FIG. 2, which is a three-dimensional view. FIG. 3 is a fragmental sectional view along line III-III of FIG. 1 with exaggerated thickness of the coating layers.

The wafer container shown in FIGS. 1, 2, and 3 is a FOUP with smooth inner walls 22a, 22b, 22c, 22d, and 22e and is intended for receiving the wafers pre-assembled with the wafer-holding cartridge, which is not shown in the drawings since the structure of this cartridge is beyond the scope of the present invention.

Reference numeral 28 designates a device for engagement of the FOUP 20 with a robotic flange of a container-transporting device (not shown). Furthermore, the FOUP 20 may have sealable openings formed in the walls therefore for various technological purposes (not shown) of the wafer-treating processes.

According to the invention, the inner walls 22a, 22b, 22c, 22d, and 22e of the FOUP 20 are coated with thin wear- and scratch resistance and easily washable coatings, e.g., of a SiO₂, which are impermeable to volatile products that can be generated in the polymer material of the container walls 22a, 22b, 22c, 22d, and 22e. The thickness of the coating must be sufficient for forming a physical barrier against diffusion of free radicals, monomers, and low-molecular-weight fragments of the polymer from which the FOUP is made. The SiO₂ layers are shown only on the walls 22a, 22d, and 22e which are seen in FIG. 3 and are designated by reference numerals 22a1, 22d1, and 22e1. Although the coatings formed on the other inner walls of the FOUP 20 are not shown, it is assumed that similar SiO₂ barrier layers are also formed on the remaining inner walls 22b and 22c.

It should be noted that typically the SiO₂ layers 22a1, 22b1, 22c1, 22d1, and 22e1 are continuous coatings having a thickness ranging from 100 to 500 Angstroms, although the upper limit of the thickness is not limited by 500 Angstroms and is selected with reference to such factors as cost, duration of the deposition process, resistance to wear and to scratching.

The cover 26 shown in FIG. 2 may be molded from the same polymer material as the FOUP casing. The cover 26 has a face surface 26a, which in the FOUP-closing position of the cover 26 sealingly closes and faces the interior of the FOUP 20. The cover 26 has a flange 26b, the shape of which corresponds to the configuration of the FOUP opening 24. All mentioned above with regard to the coating also relates to the FOUP cover 26, i.e., the face surface 26a of the cover 26 is coated with a continuous SiO₂ barrier layer 26a1 having a thickness ranging from 100 to 500 Angstroms. This layer is resistant to scratching and wear and is easily cleanable.

Since the interior of the FOUP 20 is protected from penetration of the volatile contaminants of the FOUP-wall material into the interior of the FOUP 20, it becomes possible to mold the FOUP from a low-grade polymer that may have a higher content of volatile low-molecular fragments, monomers, and free radicals than polymers of higher grades normally recommended for manufacturing wafer containers such as the FOUP 20.

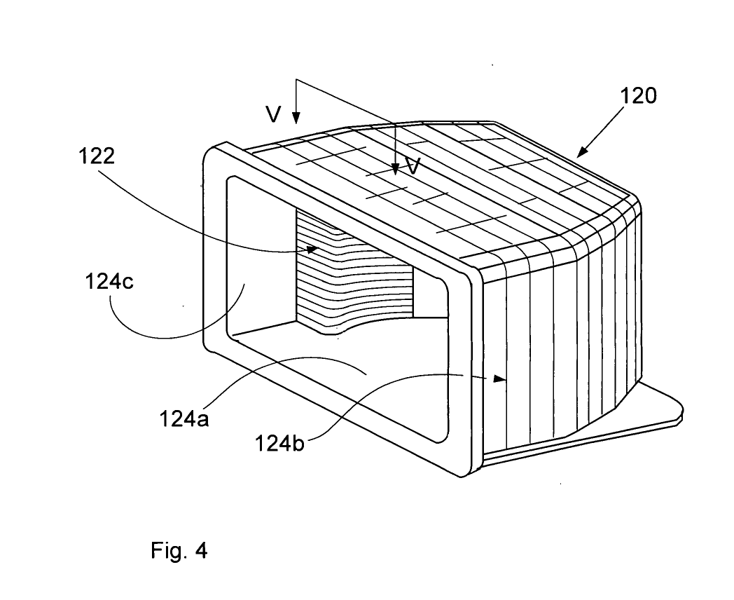

FIG. 4 is a three-dimensional view of the FOUP 120 of the invention with wafer-supporting edges 122 formed on the inner walls of the FOUP 120 by pre-coated strips 120a, 120b, . . . 120n inserted into the slots formed in the pre-coated inner walls of the container. FIG. 5 is a fragmental sectional view along line V-V of FIG. 4. In order not to complicate the drawing, in FIG. 4 the strips are shown only on one inner wall of the FOUP 120. FIG. 5 is a fragmental sectional view along line V-V of FIG. 4. The cover for the FOUP 120 is not shown since it may be the same as one shown in FIG. 2.

Similar to the FOUP20 of the previous modification, the FOUP 120 of FIGS. 4 and 5 has inner walls such as 124a, 124b, 124c . . . pre-coated with thin wear- and scratch resistance and easily washable layers, e.g., of a SiO₂, which are impermeable to volatile products that can be generated in the polymer material of the container walls 124a, 124b, 124c . . . . The thickness of the coatings must be sufficient for forming physical barriers against diffusion of free radicals, monomers, and low-molecular-weight fragments of the polymer from which the FOUP is made. The SiO₂ barrier layer is present not only on the inner surfaces of the FOUP walls but also on all surfaces of the strips 120a, 120b, . . . 120n, which are exposed to the interior of the FOUP 120. The SiO₂ layers have a thickness ranging from 100 to 500 Angstroms, although the upper limit of the thickness is not limited by 500 Angstroms and is selected with reference to such factors as cost, duration of the deposition process, and resistance to wear and to scratching. The coating layers of SiO₂ is not shown in FIG. 4 but is represented by a single continuous coating layer 128 in FIG. 5.

It is understood that in the construction with wafer-supporting edges 120a, 120b, . . . 120n it will be difficult or impossible to provide the coating layer 128 of the same uniform thickness in the areas between the wafer-supporting edges 120a, 120b, . . . 120n as in the case of smooth inner of the container as shown in FIGS. 1, 2, and 3. Therefore, according to the invention, the pre-coated inner walls 124a, 124b, 124c, . . . of the container have parallel slots 120a1, 120b1, . . . 120n1 for insertion and fixation of wafer-supporting edges 120a, 120b, . . . 120n formed by strips 120a, 120b, . . . 120n pre-coated with the same protective film of SiO₂ prior to insertion of the strips into the FOUP. The use of the pre-coated wafer-supporting edges 120a, 120b, . . . 120n will make it possible to obtain a continuous SiO₂ barrier coating layer 128.

Thus, it has been shown that the invention provides a wafer container, which has the inner surface coated with a thin barrier layer, such as a SiO₂ layer for preventing penetration of products of diffusion of polymers, such as free radicals, into the interior space of the carrier that retains a wafer. The aforementioned barrier SiO₂ layer has a thickness sufficient for protecting the surface of the wafer from contamination with volatile organic substances. The inner walls of the container of the invention are easily washable, resistant to wear and scratching, and do not produce contaminant particles caused by friction. The SiO₂ coatings on the walls of the container are applied by the PECVD method. The wafer container of the invention can be manufactured at low cost by molding it from a less expensive and lower grade polymer, e.g., from a polymer with a relatively high content of low-molecular-weight fragments.

Although the invention has been shown and described with reference to specific embodiments, it is understood that these embodiments should not be construed as limiting the areas of application of the invention and that any changes and modifications are possible, provided these changes and modifications do not depart from the scope of the attached patent claims. For example, the wafer container is not necessarily a FOUP and may comprise a wafer container of any other type suitable for storage or transportation, such as a SMIF box, FOSB, etc. The barrier layer may be applied to the container walls by a process different from PECVD, and the barrier-layer material may be different from SiO₂. The containers themselves can be made from materials different from polymers mentioned in the specification.

1. A cleanliness-improved sealable wafer container having an interior, inner walls, and a container cover sealingly attachable to the wafer container, wherein the aforementioned inner walls and the cover are made from a polymer material and wherein the aforementioned inner walls and the side of the cover that faces the aforementioned interior are coated with a continuous wear-resistant and scratch-resistant coating film.

2. The cleanliness-improved sealable wafer container of claim 1, wherein the continuous wear-resistant and scratch-resistant coating film is a uniform silicon dioxide film impermeable to products of diffusion from the aforementioned polymer material.

3. The cleanliness-improved sealable wafer container of claim 2, wherein the silicon dioxide film has the thickness ranging from 100 Angstroms to 500 Angstroms.

4. The cleanliness-improved sealable wafer container of claim 3, wherein the aforementioned polymer material is selected from the group consisting of polycarbonate (PC), acrylonitrile butadiene styrene (ABS), polypropylene (PP), polyethylene (PE), perfluoroalkoxy (PFA), and polyetheretherketone (PEEK).

5. The cleanliness-improved sealable wafer container of claim 4, wherein the aforementioned silicon dioxide film is applied by means of a plasma-enhanced chemical vapor deposition (PECVD) process.

6. The cleanliness-improved sealable wafer container of claim 1, having wafer-supporting elements on said inner walls for supporting edges of semiconductor wafers.

7. The cleanliness-improved sealable wafer container of claim 6, wherein the aforementioned wafer-supporting elements comprise a plurality of parallel ribs.

8. The cleanliness-improved sealable wafer container of claim 7, wherein the inner walls of the wafer container are pre-coated with a continuous wear-resistant and scratch-resistant coating film and have parallel slots into which the ribs are inserted and wherein the aforementioned ribs comprise plates made from a polymer material which are pre-coated with the same continuous wear-resistant and scratch-resistant coating film as the inner walls of the container.

9. The cleanliness-improved sealable wafer container of claim 7, wherein the continuous wear-resistant and scratch-resistant coating film is a silicon dioxide film.

10. The cleanliness-improved sealable wafer container of claim 9, wherein the silicon dioxide film has the thickness ranging from 100 Angstroms to 500 Angstroms.

11. The cleanliness-improved sealable wafer container of claim 10, wherein the aforementioned silicon dioxide film is applied by means of a plasma-enhanced chemical vapor deposition (PECVD) process.

12. The cleanliness-improved sealable wafer container of claim 1, wherein the aforementioned container is selected from the group consisting of a FOUP, SMIF box, and FOSB.

13. The cleanliness-improved sealable wafer container of claim 2, wherein the aforementioned container is selected from the group consisting of a FOUP, SMIF box, and FOSB.

14. The cleanliness-improved sealable wafer container of claim 4, wherein the aforementioned container is selected from the group consisting of a FOUP, SMIF box, and FOSB.
